(19) United States
(12) Patent Application Publication
(10) Pub. No.: US 2025/0126818 A1
(43) Pub. Date: Apr. 17, 2025

(54) STRUCTURE AND METHOD FOR HIGH-VOLTAGE DEVICE

(71) Applicant: TAIWAN SEMICONDUCTOR MANUFACTURING COMPANY, LTD., Hsinchu (TW)

(72) Inventors: Yuying HSIEH, Taichung (TW); Cheng-Chien LI, Hsinchu (TW); Huei-Shan WU, Keelung (TW)

(21) Appl. No.: 18/486,561

(22) Filed: Oct. 13, 2023

(51) Int. Cl. H01L 29/66; H01L 21/762; H01L 21/8238; H01L 27/092; H01L 29/06; H01L 29/423; H01L 29/775; H01L 29/78

(52) U.S. Cl. CPC H10D 30/024; H01L 21/76224; H10D 30/014; H10D 30/43; H10D 30/6211; H10D 30/6735; H10D 62/121; H10D 84/0193; H10D 84/038; H10D 84/853

(57) ABSTRACT

An IC structure and methods of forming the same are described. In some embodiments, the structure includes a fin structure disposed over a substrate, the fin structure includes first and second segments and a bottom surface between the first and second segments, and the bottom surface includes a plurality of recesses. The structure further includes a dielectric material disposed between the first and second segments of the fin structure, and the dielectric material is disposed on the bottom surface and in the plurality of recesses. The structure further includes a gate structure disposed over the first segment of the fin structure, and the gate structure covers a top surface and side surfaces of the first segment of the fin structure.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of IC processing and manufacturing, and for these advancements to be realized, similar developments in IC processing and manufacturing are needed. For example, high voltage field-effect transistors (FETs) for high voltage applications face various challenges including breakdown voltage, ON state channel resistance, drain saturation current, OFF state current, signal/noise ratio, and etc. Therefore, although conventional high voltage FETs have been generally adequate for their intended purposes, they are not satisfactory in every respect.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a top view of an integrated circuit (IC) structure including two FETs, in accordance with some embodiments.

FIG. 1B is a cross-sectional view of the IC structure of FIG. 1A, in accordance with some embodiments.

FIG. 2A is a top view of the IC structure, in accordance with some embodiments.

FIG. 2B is a cross-sectional view of the IC structure of FIG. 2A, in accordance with some embodiments.

FIGS. 3A-3C are cross-sectional side views of one of various stages of manufacturing the IC structure of FIG. 2A, in accordance with some embodiments.

FIGS. 4A-4C are various views of one of various stages of manufacturing the IC structure of FIG. 2A, in accordance with some embodiments.

FIGS. 5A-5C are cross-sectional side views of one of various stages of manufacturing the IC structure of FIG. 4C, in accordance with some embodiments.

FIGS. 6A-6D are cross-sectional side views of one of various stages of manufacturing the IC structure, in accordance with some embodiments.

FIGS. 7A-7C are cross-sectional side views of one of various stages of manufacturing the IC structure, in accordance with some embodiments.

FIG. 8 is a top view of the IC structure of FIG. 7A, in accordance with some embodiments.

### DETAILED DESCRIPTION

The following disclosure provides many different embodiments, or examples, for implementing different features. Reference numerals and/or letters may be repeated in the various examples described herein. This repetition is for the purpose of simplicity and clarity and does not in itself dictate a relationship between the various disclosed embodiments and/or configurations. Further, specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. Moreover, the formation of a feature on, connected to, and/or coupled to another feature in the present disclosure may include embodiments in which the features are formed in direct contact, and may also include embodiments in which additional features may be formed interposing the features, such that the features may not be in direct contact.

In addition, the present disclosure may repeat reference numerals and/or letters in the various examples. This repetition is for the purpose of simplicity and clarity and does not in itself dictate a relationship between the various embodiments and/or configurations discussed. Moreover, the formation of a feature on, connected to, and/or coupled to another feature in the present disclosure that follows may include embodiments in which the features are formed in direct contact, and may also include embodiments in which additional features may be formed interposing the features, such that the features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one feature relationship to another feature. The spatially relative terms are intended to cover different orientations of the device including the features. Still further, when a number or a range of numbers is described with “about,” “approximate,” and the like, the term is intended to encompass numbers that are within a reasonable range including the number described, such as within +/−10% of the number described, or other values as understood by person skilled in the art. For example, the term “about 5 nm” encompasses the dimension range from 4.5 nm to 5.5 nm.

The present disclosure relates generally to an integrated circuit (IC) structure and a method making the same, and more particularly, to a high voltage field-effect transistor (FET) structure. In various embodiments, the IC structure includes planar FET structure, and multi-gate devices, such as fin-like field effect transistors (FinFETs). The isolation regions, such as the shallow trench isolation (STI), located between the source region and the drain region of the FinFETs may be disposed on modified bottom surface of the fin structures. As a result, breakdown voltage is improved while maintaining a high current flowing through the device.

The disclosed IC structure is a high voltage metal-oxide-semiconductor-(HVMOS) device structure. The IC structure may be a hybrid structure including a planar active region, such as planar FET devices, and a three-dimensional (3D) active region, such as multi-gate FET devices. Examples of multi-gate devices include fin-like field effect transistors (FinFETs) having fin-like structures and multi-bridge-channel (MBC). An MBC transistor has a gate structure that can extend, partially or fully, around a channel region to provide access to the channel region on two or more sides. Because its gate structure surrounds the channel regions, an MBC transistor may also be referred to as a surrounding gate transistor (SGT) or a gate-all-around (GAA) transistor having a plurality of channel members vertically stacked. The IC structure may include other suitable device structure, such as forksheet FETs, and complimentary FET (CFET) structure. The IC structure and the method making the same are collectively described in detail according to various embodiments of the present disclosure.

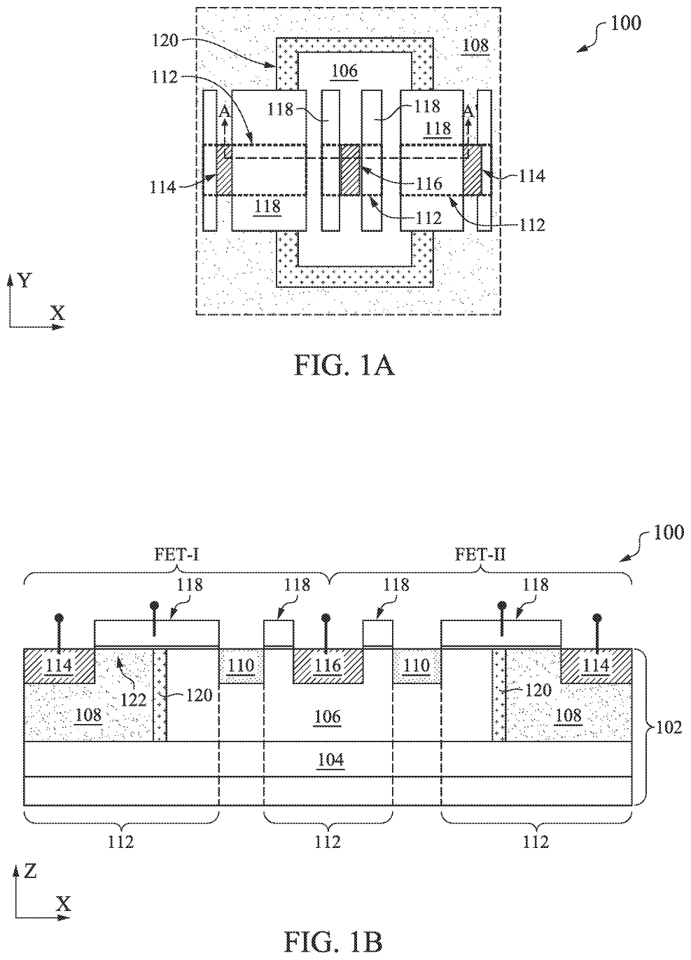

FIG. 1A is a top view of an IC structure 100 having one or more FETs, and FIG. 1B is a cross-sectional view of the IC structure 100 cut along the dashed line AA′ in FIG. 1A, in accordance with some embodiments. In the present embodiment, the FETs of the IC structure 100 is designed for high voltage application, therefore also being referred to as high voltage FET (HVFET). In the disclosed embodiments of the IC structure 100, one or more n-type FETs (nFET), is provided as an example for illustration. However, it is not intended to be limiting, the IC structure 100 may, additionally, or alternatively, include one or more p-type FETs (pFETs). In FIGS. 1A and 1B, the IC structure 100 includes two FETs configured side by side, and the two FETs share a common drain.

The IC structure 100 includes a substrate 102. The substrate 102 is a semiconductor substrate. In some embodiments, the semiconductor substrate 102 includes silicon. In some embodiments, the substrate 102 includes germanium, silicon germanium or other suitable semiconductor materials. The substrate 102 may alternatively be made of some other suitable elementary semiconductor, such as diamond or germanium; a suitable compound semiconductor, such as silicon carbide, indium arsenide, or indium phosphide; or a suitable alloy semiconductor, such as silicon germanium carbide, gallium arsenic phosphide, or gallium indium phosphide.

The substrate 102 may include a buried layer such as an n-type buried layer (NBL), a p-type buried layer (PBL), and a buried dielectric layer including a buried oxide (BOX) layer according to various embodiments. In the disclosed embodiments, the substrate 102 includes a p-type doped region 104 at a deep level of the substrate 102. The p-type dopant includes boron, gallium, indium, other suitable p-type dopant, or a combination thereof. The p-type doped region 104 is, therefore, also referred to as deep P-well 104. In some embodiments, the substrate 102 may include a BOX layer under the deep P-well 104. The deep P-well 104 may be formed by ion implantation and the BOX layer may be formed by a method referred to as separation by implanted oxygen (SIMOX).

The substrate 102 also includes an N-well region (or simply N-well) 106 (also referred to as high voltage N-well or HVNW) and a P-well region (or simply P-well) 108 formed over the deep P-well 104. The P-well 108 is configured to surround and enclose the N-well 106 in the top view, as illustrated in FIG. 1A. The N-well 106 and P-well 108 are formed by suitable method, such as ion implantation with proper dopant, implantation energy and doping dosage to achieve the desired doping type, doping level, doping thickness, and doping concentration. In the top view as illustrated in FIG. 1A, the P-well 108 is surrounding and enclosing the N-Well 106 according to the disclosed embodiments. The P-well 108 is doped with a p-type dopant such as boron, and the N-well 106 is doped with an n-type dopant such as phosphorus. In another embodiment, the N-well 106 and P-well 108 may be formed, respectively, by any suitable procedure having a plurality of processing steps, such as forming a patterned mask by a lithography process and patterning, applying an ion implantation process to the substrate 102 through the opening of the patterned mask, and removing the patterned mask afterward. In the disclosed embodiments, the N-well 106 functions as a drift region of an nFET to be formed and the P-well 108 provides a channel 122 of the nFET.

Furthermore, a neutral region 120 is inserted between the N-well 106 and the P-well 108 such that the neutral region 120 surrounds and encloses the N-well 106 and the P-well 108 surrounds and encloses the neutral region 120 in the top view, as illustrated in FIG. 1A. The neutral region 120 is designed to improve the performance of the IC structure 100, especially the performance of the high voltage FET, which includes increased breakdown voltage, reduced the resistance of the HVFET in On-state, and reduced electrical current of the HVFET in Off-state.

The neutral region 120 is a region of the semiconductor substrate 102 with no dopant. This can be achieved through a suitable method, such as redesigning the photomasks used to form the N-well 106 and the P-well 108 such that the neutral region 120 is not implanted. The neutral region 120 includes an inner edge continuously contacting the N-well 106 and an outer edge continuously contacting the P-well 108. The IC structure 100 also includes an isolation structure 110 formed on the substrate 102, thereby defining active regions 112, which are semiconductor surface regions for active devices (such as FETs) to be formed thereon. In the IC structure 100 illustrated in FIG. 1B, the active regions 112 are planar, fin-like, or a combination thereof (also being referred to as hybrid active regions). The fin-like active regions are three-dimensional (3D) active regions to increase coupling between the channels and the gates. However, it is not intended to be limiting. The active regions can have any proper profile, such as other suitable 3D profile.

The isolation structure 110 includes one or more dielectric materials and provides separation and isolation among various devices formed on the active regions 112. The isolation structure 110 may be formed by any suitable method and may have any proper geometry. In the disclosed embodiments, the isolation structure 110 includes shallow trench isolation (STI) features (also referred to by numeral 110) formed on the substrate 102. In some embodiments, the STI features 110 are formed by a suitable procedure that includes patterning to form trenches, filling the trenches with dielectric material and polishing to remove the excessive dielectric material and planarize the top surface. The patterning process includes a lithography process, etching, and may further include forming a patterned hard mask. One or more etching processes are performed on the substrate 102 through openings of the patterned hard mask, which are formed by lithography patterning and etching. The formation of the STI features 110 are further described below in accordance with some embodiments.

In some embodiments, a hard mask is deposited on the substrate 102 and is patterned by lithography process. The hard mask includes a dielectric material, such as silicon oxide, silicon nitride, silicon oxynitride, and/or other suitable material, such as metal oxide. In one embodiment, the hard mask includes a silicon oxide film and a silicon nitride film. The hard mask may be formed by thermal growth, atomic layer deposition (ALD), chemical vapor deposition (CVD), high density plasma CVD (HDP-CVD), other suitable deposition processes, or a combination thereof.

A photoresist layer (or resist) used to define the isolation structure 110 may be formed on the hard mask. A resist layer includes a photosensitive material that causes the layer to undergo a property change when exposed to light, such as ultraviolet (UV) light, deep UV (DUV) light or extreme UV (EUV) light. This property change can be used to selectively remove exposed or unexposed portions of the resist layer by a developing process referred. This procedure to form a patterned resist layer is also referred to as lithographic process.

In one embodiment, the resist layer is patterned to leave the portions of the photoresist material disposed over the substrate 102 by the lithography process. After patterning the resist, an etching process is performed on the substrate 102 to open the hard mask, thereby transferring the pattern from the resist layer to the hard mask. The remaining resist layer may be removed after the patterning the hard mask. A lithography process includes spin-on coating a resist layer, soft baking of the resist layer, mask aligning, exposing, post-exposure baking, developing the resist layer, rinsing, and drying (e.g., hard baking). Alternatively, a lithographic process may be implemented, supplemented, or replaced by other suitable methods such as mask-less photolithography, electron-beam writing, and ion-beam writing. The etching process to pattern the hard mask may include wet etching, dry etching or a combination thereof. The etching process may include multiple etching steps. For example, the silicon oxide film in the hard mask may be etched by a diluted hydro-fluorine solution and the silicon nitride film in the hard mask may be etched by a phosphoric acid solution.

Then etching process may be followed to etch the portions of the substrate 102 not covered by the patterned hard mask. The patterned hard mask is used as an etch mask during the etching processes to pattern the substrate 102. The etching processes may include any suitable etching technique such as dry etching, wet etching, and/or other etching methods (e.g., reactive ion etching (RIE)). In some embodiments, the etching process includes multiple etching steps with different etching chemistries, designed to etch the substrate 102 to form the trenches with particular trench profile for improved device performance and pattern density. In some examples, the semiconductor material of the substrate 102 may be etched by a dry etching process using a fluorine-based etchant. Particularly, the etching process applied to the substrate 102 is controlled such that the substrate 102 is partially etched. This may be achieved by controlling etching time or by controlling other etching parameters. After the etching processes, the active regions 112 are defined on the substrate 102.

One or more dielectric materials are filled in the trenches to form the STI feature 110. Suitable dielectric materials include semiconductor oxides, semiconductor nitrides, semiconductor oxynitrides, fluorinated silica glass (FSG), low-K dielectric materials, and/or combinations thereof. In various embodiments, the dielectric material is deposited using an HDP-CVD process, a sub-atmospheric CVD (SACVD) process, a high-aspect ratio process (HARP), a flowable CVD (FCVD), and/or a spin-on process.

The deposition of the dielectric material may be followed by a chemical mechanical polishing/planarization (CMP) process to remove the excessive dielectric material and planarize the top surface of the structure. The CMP process may use the patterned hard mask as a polishing stop layer to prevent polishing the semiconductor substrate 102. In some embodiments, the CMP process completely removes the patterned hard mask. Alternatively, the patterned hard mask may be removed by an etching process. Although in further embodiments, portions of the patterned hard mask remain after the CMP process.

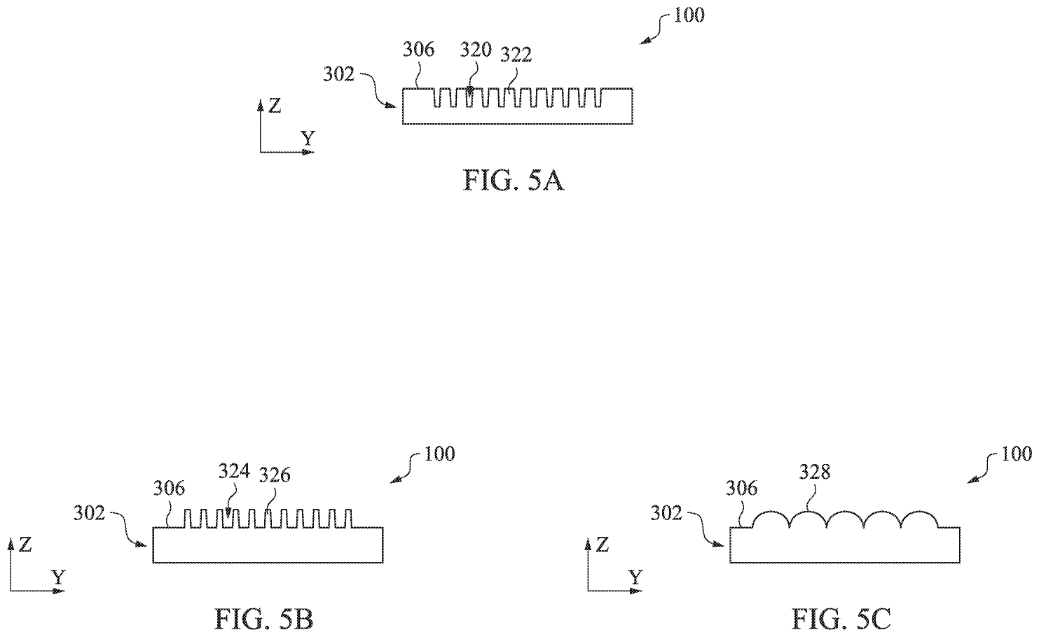

In some embodiments, the method further includes forming the fin active regions 112 by a suitable method, such as removing portions of the substrate 102 to form fin structures separated by trenches. Alternatively, the fin active regions 112 are formed by epitaxially growing fin structures extending from the substrate 102, and the fin structures are separated by trenches. In some embodiments, prior to forming the STI structure 110 in the trenches between adjacent fin structures, the bottom of the trenches are modified in order to improve breakdown voltage while maintaining a high current flowing through the device. The modification of the bottom of the trenches in the fin active regions 112 is described in detail in FIGS. 5A to 5C.

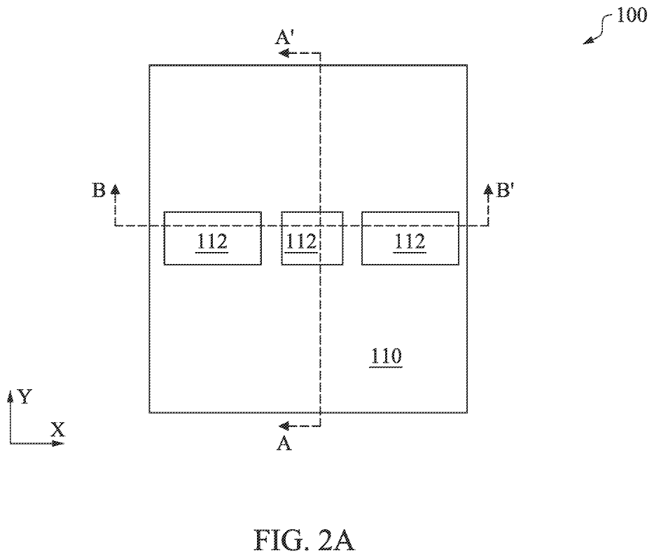

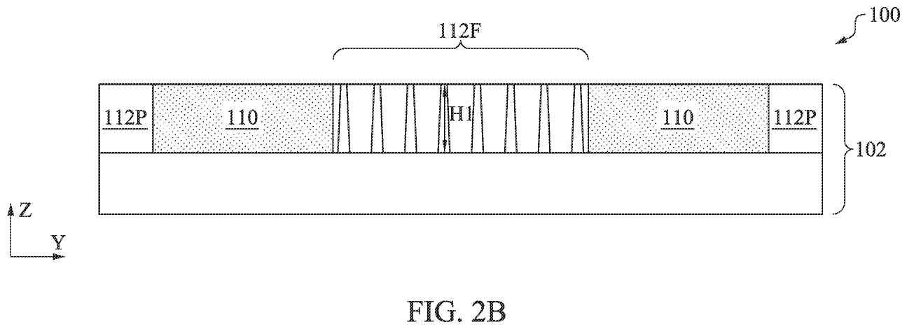

The active regions 112 are spaced from each other. The active regions 112 may have elongated shape longitudinally oriented along a first direction (X direction). A second direction (Y direction) is orthogonal to the X direction. The X and Y axes define the top surface of the substrate 102. In some embodiments, the STI feature 110 includes two extended portions to define three active regions: a first, a second and a third active region, which are illustrated in FIG. 1A and more clearly illustrated in FIG. 2A.

In some embodiments, the first active region 112 is directly formed on the N-well 106 and is disposed within the N-well 106. The first active region 112 spans between the two extended portions of the STI feature 110 along the X direction. The second active region 112 is disposed on one side (such as left side) of the first active region 112 and includes a portion of the N-well 106, the neutral region 120 and a portion of the P-well 108 along the X direction. The third active region 112 is disposed on another side (such as right side) of the first active region 112 and includes a portion of the N-well 106, the neutral region 120 and a portion of the P-well 108 along the X direction. As noted above, the active regions 112 may be hybrid active regions that includes planar active regions and fin active regions.

One or more FETs is formed in the active region 112. A FET includes a source region (or simply source) 114, a drain region (or simply drain) 116, and a gate structure 118 disposed between the source 114 and the drain 116. The source 114 and drain 116 are formed in the substrate 102 while the gate structure 118 is formed on the substrate 102. In the disclosed embodiments illustrated in FIGS. 1A and 1B, the IC structure 100 includes two nFETs (FET-I and FET-II) sharing a common drain 116.

The gate structure 118 includes a gate stack that may further include a gate dielectric layer and a gate electrode disposed on the gate dielectric layer. The gate dielectric layer includes one or more dielectric material, such as silicon oxide, high-k dielectric material, other suitable dielectric material or a combination thereof. In some embodiments, the gate dielectric layer includes one or more high-k dielectric material and may further includes an interfacial layer (such as silicon oxide) disposed between the channel and the high-k dielectric material. The high-k dielectric material may include metal oxide, metal nitride, such as LaO, AlO, ZrO, TiO, Ta₂O₅, Y₂O₃, SrTiO₃ (STO), BaTiO₃ (BTO), BaZrO, HfZrO, HfLaO, HfSiO, LaSiO, AlSiO, HfTaO, HfTiO, (Ba,Sr)TiO₃ (BST), Al₂O₃, Si₃N₄, oxynitrides (SiON), or other suitable high-k dielectric materials. The interfacial layer may include silicon oxide, silicon nitride, silicon oxynitride, and/or other suitable material. The interfacial layer may be formed by a suitable method, such as atomic layer deposition (ALD), CVD, ozone oxidation, etc. The high-k dielectric layer is deposited on the interfacial layer (if the interfacial layer presents) by a suitable technique, such as ALD, CVD, metal-organic CVD (MOCVD), PVD, thermal oxidation, combinations thereof, and/or other suitable techniques.

The gate electrode includes one or more conductive material, such as doped polysilicon, metal or metal alloy. The metal in the gate electrode includes aluminum, copper, tungsten, ruthenium, cobalt, nickel, metal silicide, other suitable metal-containing conductive material, or a combination thereof. In some embodiments, the gate electrode may include Ti, Ag, Al, TiAlN, TaC, TaCN, TaSiN, Mn, Zr, TiN, TaN, Ru, Mo, Al, WN, Cu, W, any suitable materials, or a combination thereof.

The gate structures 118 may further include gate sidewall features (or gate spacers) formed on the sidewalls of the gate electrode and the gate dielectric layer. The gate spacers provide isolation between gate electrode and source/drain regions. The gate spacers may include any suitable dielectric material, such as a semiconductor oxide, a semiconductor nitride, a semiconductor carbide, a semiconductor oxynitride, other suitable dielectric materials, and/or combinations thereof. The gate spacers may have multiple films, such as two films (a silicon oxide film and a silicon nitride film) or three films (a silicon oxide film; a silicon nitride film; and a silicon oxide film). The formation of the gate spacers includes deposition and anisotropic etching, such as dry etching.

The formation of the gate structure 118 includes depositing various gate materials and patterning the deposited gate materials using a procedure that includes a lithography process and etching. In some embodiments, the gate structure 118 may be formed by a gate replacement procedure, in which a dummy gate structure is formed and is replaced at later stage, such as after the formation of the source 114 and drain 116, to avoid undesired impact of a thermal process to the gate structure 118.

In some embodiments, the gate structure 118 is fragmented to have multiple segments for various fabrication benefits, such as tuning the pattern density and improving processing (such CMP) uniformity. In the disclosed embodiments, the gate structure 118 for the first nFET (FET-I) includes a first segment disposed between the drain 116 and the STI feature 110; and a second segment disposed between the source 114 and the STI feature 110. In furtherance of the embodiment, the first segment of the gate structure 118 is formed for the fabrication benefits and is floating, which means that it is not configured to be biased and is not functioning as a gate of the first nFET. The second segment of the gate structure 118 is configured to be connected to a power signal line so that it is biased as the functional gate of the first nFET. Due to different functions of the first and second segments of the gate structure 118, the first and second segments may be designed with different dimensions. For example, the second segment may have a dimension along the X direction greater than that of the first segment. In some embodiments, the second segment of the gate structure 118 is landing on the P-well 108, the neutral region 120 and the N-well 106. The second segment of the gate structure 118 capacitively couple to the P-well 108 so to control the channel 122 of the first nFET. The channel 122 is the portion of the P-well 108 underlying the second segment of the gate structure 118. The second nFET (FET-II) is similar to the first nFET in terms of layout and configuration. For example, the gate structure 118 of the second nFET also includes two segments, one segment is floating and is disposed between the drain 116 and STI feature 110; and another segment is biased and is disposed between the STI feature 110 and the source 114.

The source 114 and the drain 116 are semiconductor features doped with proper dopant. For example, in the embodiment illustrated in FIGS. 1A and 1B, an nFET is formed, and the source 114 and the drain 116 are doped with an n-type dopant, such as phosphorous. It is only illustrative and not intended to be limiting. It is understood that one or more pFETs are alternatively or additionally formed. For a pFET, the source 114 and the drain 116 are doped with p-type dopant. Furthermore, the doped wells 106 and 108 are swapped to be p-type well and n-type well accordingly.

In some embodiments, the source 114 and drain 116 are formed by diffusion or ion implantation. In some embodiments, the source 114 and the drain 116 are formed by a procedure that includes etching the substrate 102 to form source/drain (S/D) recesses; and epitaxially growing one or more semiconductor material, such as silicon, or silicon germanium to achieve the strain effect with enhanced carrier mobility. In this case, the dopant may be introduced into the source 114 and the drain 116 during the epitaxial growth. In some embodiments, a thermal annealing process may be followed to activate the source 114 and the drain 116. In this disclosure, a source region and a drain region are interchangeably used, and the structures thereof are substantially the same. Furthermore, source/drain region(s) may refer to a source or a drain, individually or collectively dependent upon the context.

In the described embodiment illustrated in FIGS. 1A and 1B, the IC structure 100 includes two nFETs disposed side by side with a common drain 116. As illustrated in FIG. 1B, the source 114 on the left side, the drain 116, and the portions of the gate structure 118 (such as the second segment) on the left side of the drain 116 constitute a first nFET (FET-I); and the source 114 on the right side, the drain 116, and the portions of the gate structure 118 on the right side of the drain 116 constitute a second nFET (FET-II). The first and second nFETs share a common drain 116. In some embodiments, the common drain 116 is formed in the N-well 106 while the sources 114 are formed in the P-well 108.

FIG. 2A is a top view of the IC structure 100 having two high voltage FETs, and FIG. 2B is a cross-sectional view of the IC structure 100, cut along the dashed line AA′ of FIG. 2A. The FIGS. 2A and 2B only illustrate the STI feature 110 and the active regions 112 for simplicity.

As illustrated in FIG. 2A, the IC structure 100 includes three active regions 112, left, central and right active regions. In some embodiments, the IC structure 100 includes a hybrid structure having planar active regions and 3D active regions. For example, the three active regions 112 shown in FIG. 2A are 3D active regions having FinFETs, and the IC structure 100 further includes planar regions 112P, as shown in FIG. 2B. The planar regions 112P are not shown in FIG. 2A for simplicity. As shown in FIG. 2B, the active region 112F, which is the central active region 112 shown in FIG. 2A, includes a plurality of fin structures as channels. The gate stacks and the STI feature disposed between adjacent fin structures are not shown in FIG. 2B for simplicity. In some embodiments, each fin structure has a height H1 ranging from about 100 nm to about 120 nm. The active region 112F is disposed between two planar active regions 112P, and the active regions 112F and 112P are separated by the STI feature 110. In some embodiments, one or more FETs are formed across the planar active region 112P and the 3D active region 112F.

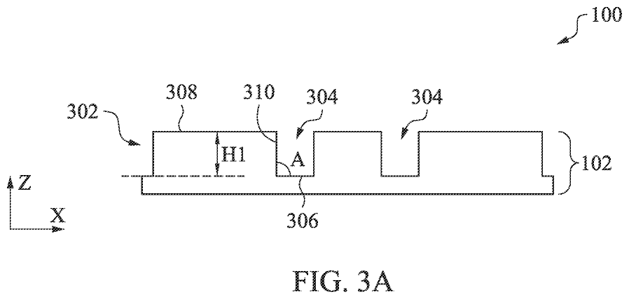

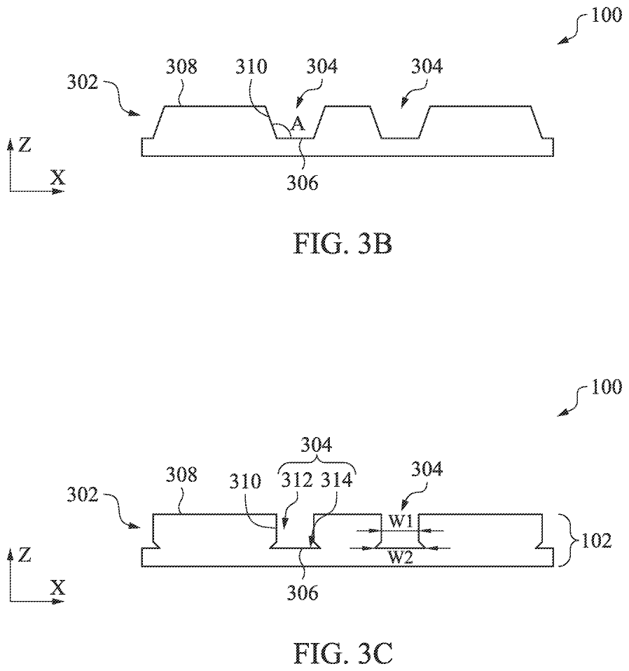

FIGS. 3A-3C are cross-sectional side views, cut along the dashed line BB′ of FIG. 2A, of one of various stages of manufacturing the IC structure 100 of FIG. 2A, in accordance with some embodiments. As shown in FIG. 3A, a fin structure 302 is formed from the substrate 102. The fin structure 302 may be one of the fin structures shown in FIG. 2B. When forming the fin structure 302, the planar active regions 112P shown in FIG. 2B may be protected by a mask. As shown in FIG. 3A, after the fin structure 302 is formed, openings 304 are formed in the fin structure 302. The openings 304 form a plurality of segments of the fin structure 302. In other words, the fin structure 302 includes discrete segments in the X direction. The openings 304 may be formed by any suitable process. In some embodiments, a patterned mask layer (not shown) is formed on the fin structure 302, and the pattern of the patterned mask layer is transferred to the fin structure 302. Lithography and etching processes may be performed to pattern the mask layer and to transfer the pattern to the fin structure 302. The fin structure 302 may have a height H1 ranging from about 100 nm to about 120 nm. The height H1 may be measured from a bottom surface 306 of the opening 304 to a top surface 308 of the fin structure 302. Each opening 304 may be defined by side surfaces 310 and the bottom surface 306. The side surface 310 and the bottom surface 306 form an angle A. In some embodiments, the angle A is a substantially right angle ranging from about 89 degrees to about 91 degrees.

In some embodiments, the angle A is an acute angle or an obtuse angle, as shown in FIG. 3B. The angle A may range from about 70 degrees to about 85 degrees or from about 95 degrees to about 120 degrees. The angle A may be controlled by the etching process to form the openings 304. Process conditions such as plasma power and/or bias power may be adjusted to form the predetermined angle A. For example, the openings 304 having the right or acute angle A may be formed by an etching process including a first process condition followed by a second process condition. The second process condition may have a higher plasma power and/or higher bias power than the first process condition. In some embodiments, the first process condition includes flowing a first etchant into the processing chamber, and the second process condition includes flowing a second etchant different from the first etchant into the processing chamber.

In some embodiments, the opening 304 includes a first portion 312 and a second portion 314 located below the first portion 312, as shown in FIG. 3C. The first portion 312 may include a substantially constant width W1, and the second portion 312 may include varying width W2. In some embodiments, the varying width W2 increases in a direction towards the bottom surface 306. The opening 314 with the first portion 312 and the second portion 314 may be formed by a two-step etching process. For example, the first step includes an anisotropic etching process, and the second step includes an isotropic etching process performed after the first step. In some embodiments, a dry etching process is performed first, followed by a wet etching process to form the opening 304 with the first portion 312 and the second portion 314. In some embodiments, the opening 304 with the first portion 312 and the second portion 314 may be formed by an etching process including a first process condition followed by a second process condition, similar to the etching process to form the opening 304 having the right or acute angle A. In some embodiments, the plasma power and/or the bias power of the second process condition is substantially greater than the plasma power and/or the bias power of the first process condition. In some embodiments, the first process condition includes etchants having a first carbon to fluorine ratio, and the second process condition includes etchants having a second carbon to fluorine ratio substantially greater than the first carbon to fluorine ratio.

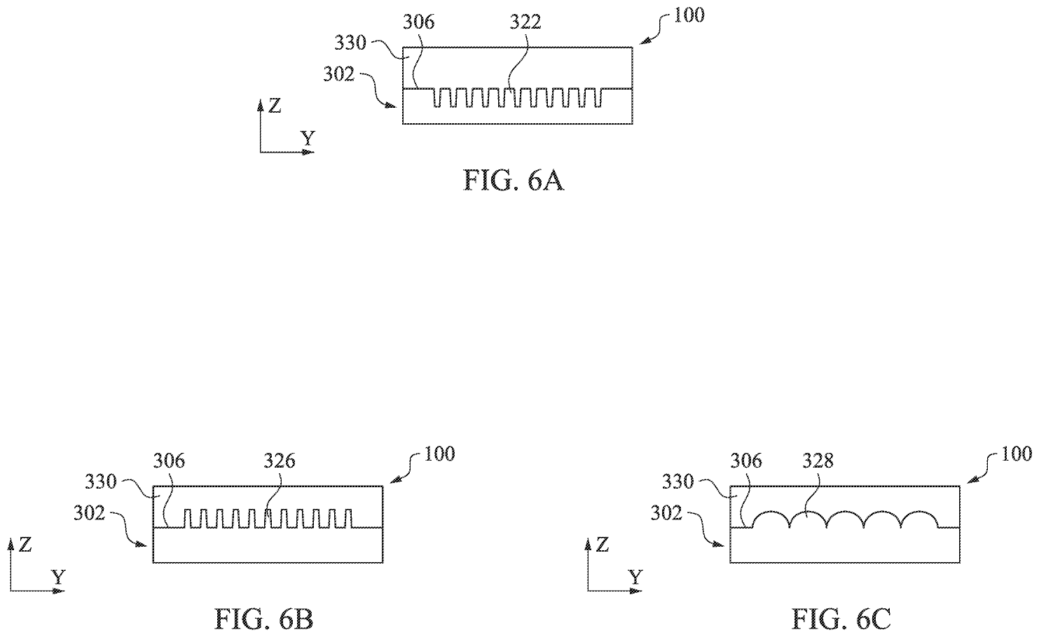

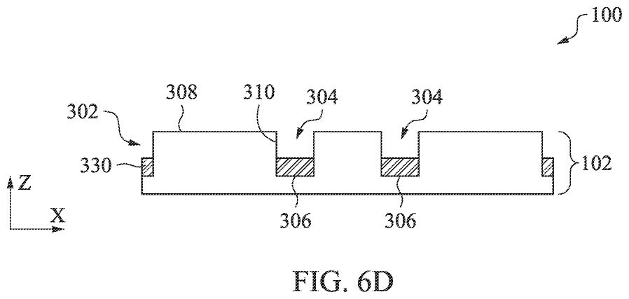

The openings 304 having different shapes may have different benefits. For example, the opening 304 having the first portion 312 and the second portion 314 may have a more stable subsequently formed STI feature 330 (FIGS. 6A-6D).

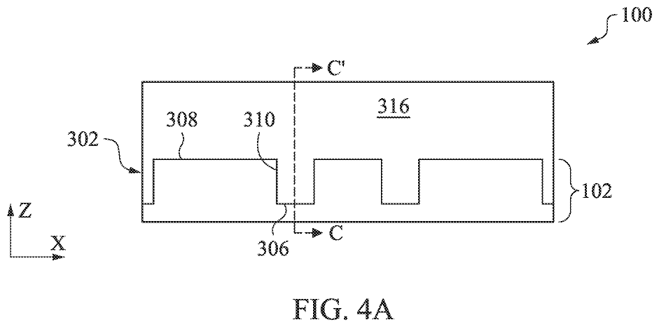

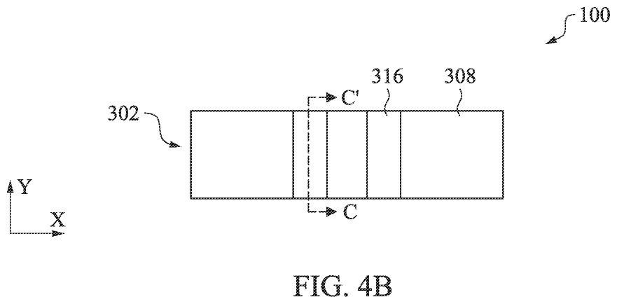

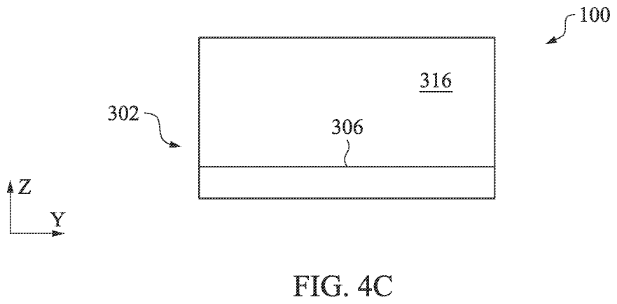

FIGS. 4A-4C are various views of one of various stages of manufacturing the IC structure 100 of FIG. 2A, in accordance with some embodiments. FIG. 4A is a cross-sectional side view of the IC structure 100 cut along the dashed line BB′ of FIG. 2A. After forming the openings 304, a mask layer 316 is deposited into the openings 304 and on the fin structure 302. In some embodiments, a mask layer (not shown) is already formed on portions of the fin structure 302, such as on the top surface 308, and the mask layer 316 is deposited on the mask layer. The mask layer 316 may include any suitable material having different etch selectivity as the fin structure 302. In some embodiments, the mask layer 316 includes a dielectric material. In some embodiments, the mask layer 316 is a bottom anti-reflective coating (BARC) layer. FIG. 4B is a top view of the IC structure 100 of FIG. 4A, and FIG. 4C is a cross-sectional side view of the IC structure 100 cut along the dashed line CC′ of FIG. 4A or 4B.

In some embodiments, the mask layer 316 may be planarized so a top surface of the mask layer 316 is substantially planar. Next, a resist layer (not shown) is deposited on the mask layer 316 and patterned. The patterning of the resist layer may include a lithography process and one or more etching processes. Then, the pattern of the resist layer is transferred to the mask layer 316, and then transferred to the bottom surface 306 of the fin structure 302. The transferring of the pattern to the mask layer 316 and to the bottom surface 306 of the fin structure 302 may be performed by etching processes. The transferring of the pattern to the bottom surface 306 modifies the bottom surface 306, and FIGS. 5A-5C illustrate various modified bottom surfaces 306 in accordance with some embodiments.

FIGS. 5A-5C are cross-sectional side views of one of various stages of manufacturing the IC structure 100 of FIG. 4C, in accordance with some embodiments. As shown in FIG. 5A, the modified bottom surface 306 of the fin structure 302 includes a plurality of recesses 320, and the recesses 320 define a plurality of fins 322. The depth of the recess 320 may range from about 5 nm to about 20 nm, and the height of the fin 322 may range from about 5 nm to about 20 nm. As shown in FIG. 5B, in some embodiments, the modified bottom surface 306 includes a plurality of protrusions 326 separated by a plurality of openings 324. The protrusions 326 extend from the bottom surface 306, and each protrusion 326 may have a height ranging from about 5 nm to about 20 nm. In some embodiments, as shown in FIG. 5C, the modified bottom surface 306 includes a plurality of bumps 328. Each bump 328 may have a height ranging from about 5 nm to about 20 nm.

FIGS. 6A-6D are cross-sectional side views of one of various stages of manufacturing the IC structure 100, in accordance with some embodiments. As shown in FIGS. 6A-6C, after modifying the bottom surface 306, the STI feature 330 is formed in the openings 304 on the modified bottom surface 306 of the fin structure 302. The STI feature 330 may be the STI feature 110 shown in FIGS. 1A and 1B. By forming the STI feature 330 on the modified bottom surface 306, breakdown voltage is improved while maintaining a high current flowing through the device. The STI feature 330 may be formed by first depositing a dielectric material in the openings 304 and on the fin structure 302, followed by a planarization process to remove the portions of the dielectric material disposed on the fin structure 302. Next, the dielectric material is recessed to form the STI feature 330. FIG. 6D shows the STI feature 330 is formed between segments of the fin structure 302.

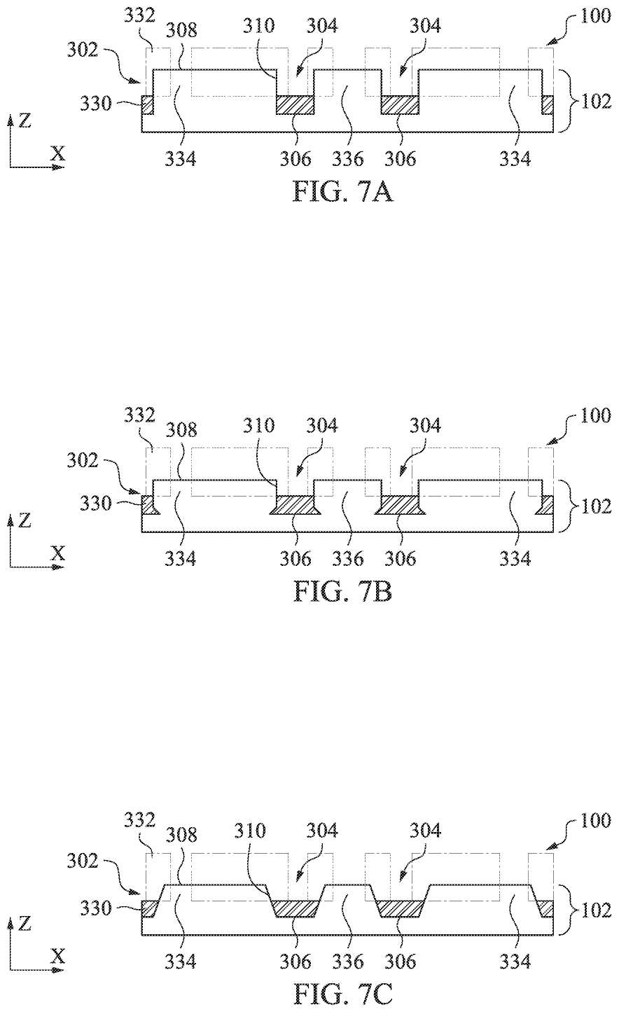

FIGS. 7A-7C are cross-sectional side views of one of various stages of manufacturing the IC structure 100 of FIG. 6, in accordance with some embodiments. As shown in FIGS. 7A, 7B, and 7C, a gate structure 332 is formed over the fin structure 302. The gate structure 332 may include the same layers as the gate structure 118. However, the gate structure 332 covers the top surface and side surfaces of the fin structure 302. Similar to the gate structure 118, the gate structure 332 also includes a plurality of segments. As described above, the plurality of segments are for various fabrication benefits, such as tuning the pattern density and improving processing (such CMP) uniformity. Some segments may be floating, while other segments may be connected to power signal lines. In some embodiments, the segments of the gate structure 332 having the largest dimension in the X axis are functional gate structures.

The IC structure 100 further includes sources 334 and drains 336, as shown in FIGS. 7A, 7B, and 7C. In some embodiments, the IC structure 100 shown in FIGS. 7A, 7B, and 7C includes two FETs sharing a drain 336. The source 334 and the drain 336 may include the same materials as the source 114 and the drain 116 and may be formed by the same process as the source 114 and the drain 116. As described above, the FETs may be HVFETs, and a large current may flow from the sources 334 to the drain 336. The large current flows through the portion of the fin structure 302 having the modified bottom surface 306. Because of the modified bottom surface 306, the breakdown voltage of the STI features 330 is improved while maintaining the large current flowing therethrough.

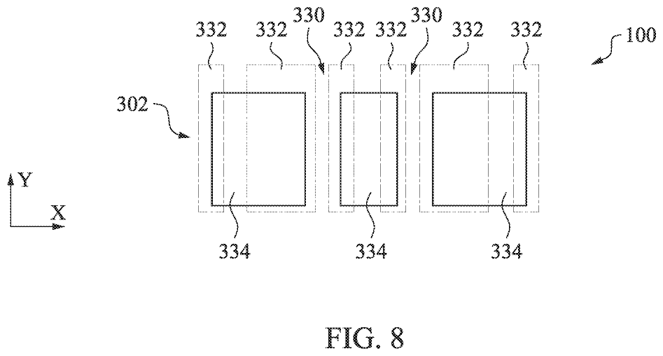

FIG. 8 is a top view of the IC structure 100 of FIG. 7A (or 7B, 7C), in accordance with some embodiments. As shown in FIG. 8, the gate structure 332 covers the top surface and the side surfaces of the fin structure 302. The STI feature 330 and the modified bottom surface 306 (FIGS. 5A, 5B, 5C) are located between the source 334 and the drain 336.

The present disclosure provides an IC structure having one or more HVFET devices and a method making the same. As described above, the IC structure includes a fin structure 302 having one or more openings 304 formed therein. A bottom surface 306 of the fin structure 302 at the bottom of each opening 304 includes recesses 320, protrusions 326, or bumps 328. Various features are implemented in the disclosed IC structure to achieve the enhanced performance including increased breakdown voltage of the STI feature 330, reduced leakage current, and increased current in the On state. Furthermore, the HVFET device of the IC structure may be formed in the fin active regions or formed with other three-dimensional FET structure, such as a nano structure having multiple channels vertically stacked, such as a gate-all-around (GAA) structure, or a CFET structure with a nFET and a pFET vertically stacked on each other.

An embodiment is an IC structure. The structure includes a fin structure disposed over a substrate, the fin structure includes first and second segments and a bottom surface between the first and second segments, and the bottom surface includes a plurality of recesses. The structure further includes a dielectric material disposed between the first and second segments of the fin structure, and the dielectric material is disposed on the bottom surface and in the plurality of recesses. The structure further includes a gate structure disposed over the first segment of the fin structure, and the gate structure covers a top surface and side surfaces of the first segment of the fin structure.

Another embodiment is an IC structure. The IC structure includes a first field-effect transistor (FET) disposed over a substrate. The first FET includes a first source, a drain, a first gate structure disposed between the first source and the drain, and a first shallow trench isolation (STI) feature disposed between the first source and the drain. The first STI feature is disposed on a first bottom surface of the substrate, and the first bottom surface includes a first plurality of bumps. The IC structure further includes a second FET disposed over the substrate. The second FET includes a second source, the drain, a second gate structure disposed between the second source and the drain, and a second STI feature disposed between the second source and the drain.

A further embodiment is a method. The method includes forming a fin structure from a substrate and forming a plurality of openings in the fin structure. Each opening has a bottom surface. The method further includes depositing a mask layer in the opening, patterning the mask layer, transferring a pattern of the mask layer to the bottom surface to modify the bottom surface in each opening, depositing a dielectric material in the openings and on the modified bottom surface in each opening, and forming a gate structure cover a top surface and side surfaces of the fin structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit (IC) structure, comprising:
a fin structure disposed over a substrate, wherein the fin structure includes first and second segments and a bottom surface between the first and second segments, and the bottom surface includes a plurality of recesses;
a dielectric material disposed between the first and second segments of the fin structure, wherein the dielectric material is disposed on the bottom surface and in the plurality of recesses; and
a gate structure disposed over the first segment of the fin structure, wherein the gate structure covers a top surface and side surfaces of the first segment of the fin structure.

2. The IC structure of claim 1, further comprising a source disposed in the first segment of the fin structure and a drain disposed in the second segment of the fin structure.

3. The IC structure of claim 2, wherein the bottom surface and the dielectric material are disposed between the source and the drain.

4. The IC structure of claim 1, wherein the fin structure has a height ranging from about 100 nm to about 120 nm.

5. The IC structure of claim 4, wherein the plurality of recesses define a plurality of fins, and each fin has a height ranging from about 5 nm to about 20 nm.

6. The IC structure of claim 2, wherein the gate structure comprises first, second, third, and fourth segments, the first and second segments of the gate structure are disposed over the first segment of the fin structure, and the third and fourth segments of the gate structure are disposed over the second segment of the fin structure.

7. The IC structure of claim 6, wherein the source is disposed between the first and second segments of the gate structure and the drain is disposed between the third and fourth segments of the gate structure from a top view.

8. An integrated circuit (IC) structure, comprising:
a first field-effect transistor (FET) disposed over a substrate, comprising:
a first source;
a drain;
a first gate structure disposed between the first source and the drain; and
a first shallow trench isolation (STI) feature disposed between the first source and the drain, wherein the first STI feature is disposed on a first bottom surface of the substrate, and the first bottom surface comprises a first plurality of bumps; and
a second FET disposed over the substrate, comprising:
a second source;
the drain;
a second gate structure disposed between the second source and the drain; and
a second STI feature disposed between the second source and the drain.

9. The IC structure of claim 8, wherein the first gate structure is disposed over a segment of a fin structure.

10. The IC structure of claim 9, wherein the segment of the fin structure has a height ranging from about 100 nm to about 120 nm.

11. The IC structure of claim 10, wherein each bump of the first plurality of bumps has a height ranging from about 5 nm to about 20 nm.

12. The IC structure of claim 10, wherein the segment of the fin structure has a side surface, and an angle is formed between the side surface and the first bottom surface.

13. The IC structure of claim 12, wherein the angle is an acute angle.

14. The IC structure of claim 12, wherein the angle is an obtuse angle.

15. The IC structure of claim 8, wherein the second STI feature is disposed on a second bottom surface of the substrate, and the second bottom surface comprises a second plurality of bumps.

16. A method, comprising:
forming a fin structure from a substrate;
forming a plurality of openings in the fin structure, wherein each opening has a bottom surface;
depositing a mask layer in the opening;
patterning the mask layer;
transferring a pattern of the mask layer to the bottom surface to modify the bottom surface in each opening;
depositing a dielectric material in the openings and on the modified bottom surface in each opening; and
forming a gate structure cover a top surface and side surfaces of the fin structure.

17. The method of claim 16, wherein the transferring the pattern of the mask layer to the bottom surface comprises forming a plurality of recesses in the bottom surface.

18. The method of claim 16, wherein the transferring the pattern of the mask layer to the bottom surface comprises forming a plurality of protrusions in the bottom surface.

19. The method of claim 16, wherein the transferring the pattern of the mask layer to the bottom surface comprises forming a plurality of bumps in the bottom surface.

20. The method of claim 16, wherein each opening includes a first portion having a first width and a second portion located below the first portion, and the second portion has a second width substantially greater than the first width.
